(19) United States
(12) Patent Application Publication
(10) Pub. No.: US 2008/0202853 A1
(43) Pub. Date: Aug. 28, 2008

(54) Transmission Including Magnetic Sensor Device

(75) Inventor: Shiro Ogami, Kariya-shi (JP)

Correspondence Address: BUCHANAN, INGERSOLL & ROONEY PC, POST OFFICE BOX 1404, ALEXANDRIA, VA, 22313-1404, US

(73) Assignee: AISIN AI CO., LTD., Nishio-shi (JP)

(21) Appl. No.: 12/035,162

(22) Filed: Feb. 21, 2008

(30) Foreign Application Priority Data
Feb. 22, 2007 (JP) 2007-042813

(51) Int. Cl. F16H 57/04; G01R 33/12

(52) U.S. Cl. 184/6.12; 324/200

(57) ABSTRACT

A transmission includes first and second transmission shafts arranged parallel to each other and rotatably supported in a casing, plural gear trains arranged between the first and second transmission shafts, each gear train including a drive gear and a driven gear engaging with each other, the first and second transmission shafts transmitting power therebetween by means of one of the gear trains, a magnetic sensor device including a magnetic portion generating a magnetic field and a detection portion detecting a change of the magnetic field generated by the magnetic portion, a lubricant supply pump for suctioning a lubricant stored at a bottom portion in the casing and for sending the lubricant suctioned, and a lubricant supply pipe for ejecting the lubricant sent from the lubricant supply pump to the magnetic portion exposed within the casing.

### CROSS REFERENCE TO RELATED APPLICATIONS

This application is based on and claims priority under 35 U.S.C. § 119 to Japanese Patent Application No. 2007-042813, filed on Feb. 22, 2007, the entire content of which is incorporated herein by reference.

### FIELD OF THE INVENTION

This invention generally relates to a transmission. More particularly, the invention pertains to a transmission including a magnetic sensor device.

### BACKGROUND

An automatic transmission for a vehicle provided with a fluid-type torque converter is widely known. However, such fluid-type torque converter may suffer from slippages when transmitting power, leading to a loss of transmission efficiency. In light of the foregoing, automation of a transmission apparatus that includes a gear-type manual transmission has been suggested. In order to control such transmission apparatus, a detection of an operating state such as a rotation speed of a transmission shaft and a stroke position of a shift fork is necessary.

JP7191048A discloses, as a prior art, a magnetic type rotation detecting device provided in a transmission for a vehicle. The transmission disclosed includes a gear for driving wheels and provided at an end portion formed by extending from an engine shaft of an engine, and the like that drives a vehicle. A sensor portion provided in the vicinity of an outer circumferential surface of the gear detects a rotating speed of the gear so as to detect a vehicle speed, and the like. The sensor portion includes a magnetic portion at an inside and a detection portion at an edge not being in contact with a teeth portion of the gear that serves as a detected object. A magnetic field generated by the magnetic portion disposed inside the sensor portion changes in association with a movement of the teeth portion of the gear. The sensor portion detects the change of the magnetic field so as to acquire an electric signal corresponding to a rotation state of the gear.

In addition, JP2006029441 discloses, as a prior art, a magnetic type position detecting device for detecting a stroke position of a shift fork. The detecting device disclosed detects a displacement of the shift fork in an axial direction, which is required for an automation of a so-called dual clutch manual transmission. A magnetic portion for detecting the stroke position of the shift fork is provided at a bracket that is formed at a joint portion between the shift fork and a shift shaft in an extending manner. Then, a magnetic sensor is provided at an inner wall of a casing so as to face the magnet.

Within a casing of a transmission, fine iron powder that may be generated at portions such as a mesh portion of gears and a bearing portion is mixed into a lubricant. According to each of the aforementioned magnetic type detecting devices, the iron powder in the lubricant may be intensively absorbed by the magnetic portion to thereby change a magnetic path thereof. Then, the magnetic field generated by the magnetic portion is changed, which adversely affects an operation of the detecting device. As a result, a possible detection error in the operating state of the transmission may deteriorate the reliability of a gearshift control system. In order to solve such the problem, the detecting device is mounted onto a portion where the lubricant is unlikely to flows which is insufficient though to solve the problem.

A need thus exists for a transmission including a magnetic sensor which is not susceptible to the drawback mentioned above.

### SUMMARY OF THE INVENTION

According to an aspect of the present invention, a transmission includes first and second transmission shafts arranged parallel to each other and rotatably supported in a casing) plural gear trains arranged between the first and second transmission shafts, each gear train including a drive gear and a driven gear engaging with each other, the first and second transmission shafts transmitting power therebetween by means of one of the gear trains, a magnetic sensor device including a magnetic portion generating a magnetic field and a detection portion detecting a change of the magnetic field generated by the magnetic portion, a lubricant supply pump for suctioning a lubricant stored at a bottom portion in the casing and for sending the lubricant suctioned, and a lubricant supply pipe for ejecting the lubricant sent from the lubricant supply pump to the magnetic portion exposed within the casing.

### BRIEF DESCRIPTION OF THE DRAWINGS

The foregoing and additional features and characteristics of the present invention will become more apparent from the following detailed description considered with reference to the accompanying drawings, wherein:

FIG. 1 is a plan view illustrating a main structure of a transmission including a magnetic sensor device according to an embodiment of the present invention;

FIG. 2 is a cross sectional view taken along the line II-II in FIG. 1; and

FIG. 3 is a diagram illustrating a lubricant supply system, according to the embodiment of the present invention.

### DETAILED DESCRIPTION

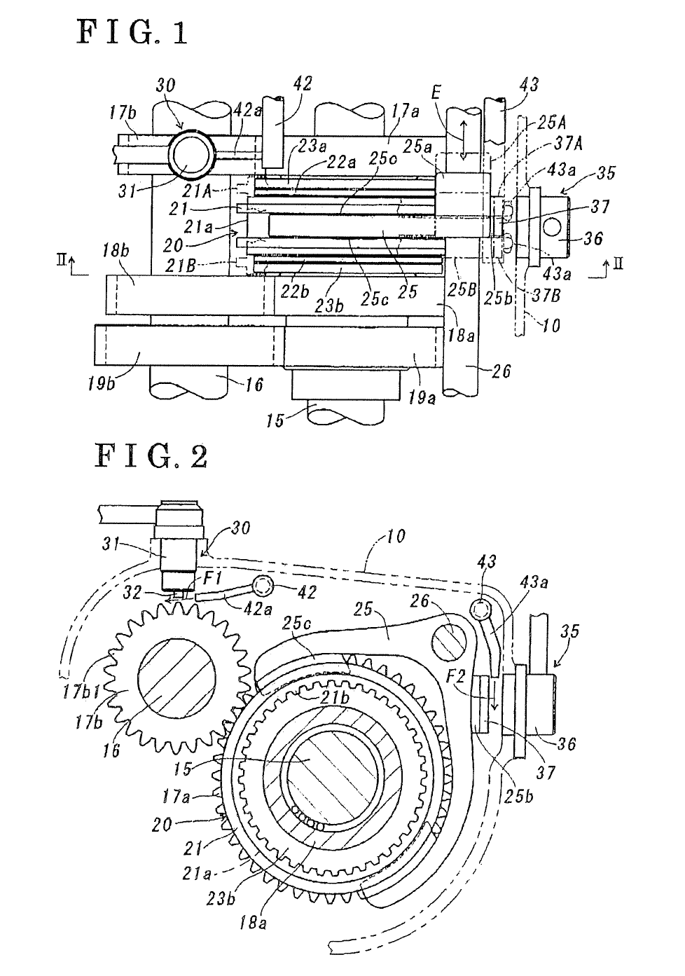

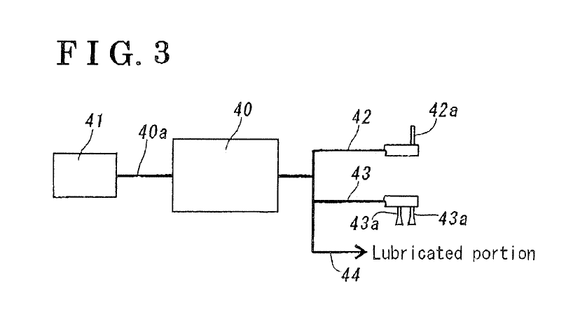

An embodiment of the present invention will be explained with reference to FIGS. 1 to 3. As illustrated in FIGS. 1 and 2, a transmission including a magnetic sensor device according to the present embodiment includes an input shaft 15 serving as a first transmission shaft, an output shaft 16 serving as a second transmission shaft, and multiple gear trains all of which are accommodated in a casing 10. The input shaft 15 and the output shaft 16 are arranged parallel to each other and are rotatably supported in the casing 10. The multiple gear trains are arranged between the input shaft 15 and the output shaft 16. Specifically, each of the gear trains is constituted by a drive gear and a driven gear engaging with each other. For example, a first gear train is constituted by a first drive gear 17a and a first driven gear 17b, a second gear train is constituted by a second drive gear 18a and a second driven gear 18b, and the like. The drive gears 17a, 18a, 19a, and the like are rotatably supported at the input shaft 15 and are selectively connected thereto by means of a synchromesh mechanism 20. On the other hand, the driven gears 17b, 18b, 19b, and the like are fixed to the output shaft 16. Then, power transmission is performed between the input shaft 15 and the output shaft 16 through one of the gear trains 17a and 17b, 18a and 18b, 19a and 19b, and the like. According to the present embodiment, alternatively, a portion or all of the drive gears 17a, 18a, 19a, and the like may be fixed to the input shaft 15 while a portion or all of the driven gears 17b, 18b, 19b, and the like may be rotatably supported at the output shaft 16 so that each of the driven gears 17b, 18b, 19b, and the like is selectively connected to the output shaft 16 by means of the synchromesh mechanism 20.

In addition, a rotation speed sensor 30 (magnetic sensor device) and a stroke position sensor 35 (magnetic sensor device) are accommodated in the casing 10. The rotation speed sensor 30 detects a rotation speed of the driven gear 17b fixed to the output shaft 16 that is connected to drive wheels. The stroke position sensor 35 detects a stroke position of a shift fork 25 (operation member) that selects one of the gear trains 17a and 17b, 18a and 18b, 19a and 19b, and the like by means of the synchromesh mechanism 20 for shifting gears. Further, a lubricant supply pump 40 is accommodated in the casing 10 so as to suction a lubricant stored at a bottom portion of the casing 10 and to eject the suctioned lubricant towards a tip end portion of a magnetic portion 32 provided at the rotation speed sensor 30 and towards a tip end portion of a magnetic portion 37 provided at the stroke position sensor 35 by means of first and second lubricant supply pipes 42 and 43, respectively.

The synchromesh mechanism 20 according to the present embodiment has a known structure including a sleeve 21, first and second gear pieces 23a and 23b, and first and second synchronizer rings 22a and 22b. The sleeve 21 is splined in an axially movable manner to an outer periphery of a clutch hub (not shown) that is coaxially fixed to the input shaft 15. The first and second gear pieces 23a and 23b are coaxially fixed to the drive gears 17a and 18b, respectively, that are arranged on axially both sides of the sleeve 21, respectively. The first and second synchronizer rings 22a and 22b axe arranged between the sleeve 21, and both the gear pieces 23a and 23b, respectively, so as to be axially movable by a small distance. Further, the first and second synchronizer rings 22a and 22b are frictionally engageable, by means of respective conic surfaces thereof, with the first and second gear pieces 23a and 23b. Then, an external spline is formed at each outer peripheral edge of the synchronizer rings 22a and 22b, and gear pieces 23a and 23b so as to axially engage with an internal spline 21b formed at an inner periphery of the sleeve 21. In this case, a set of the drive gear, the gear piece fixed to the drive gear, and the synchronizer ring frictionally engageable with the gear piece may be provided at axially one side, instead of both sides, of the synchromesh mechanism.

The shift fork 25 that brings the sleeve 21 of the synchromesh mechanism 20 to move is mounted via a boss portion 25a onto a fork shaft 26. The fork shaft 26 is guided and supported at the casing 10 so as to be axially movable and parallel to the input shaft 15 and the output shaft 16. The shift fork 25 includes two fork end portions of which inner sides are formed by engagement portions 25c, respectively, which are slidably engageable with an annular groove 21a formed at an outer periphery of the sleeve 21. The fork shaft 26 is brought to reciprocate in an axial direction thereof as shown by an arrow E in FIG. 1 by means of an automatic actuator (not shown). As a result, the sleeve 21 is also brought to reciprocate in an axial direction thereof.

In a neutral position of the transmission (i.e., a neutral position of the shift fork 25 and the fork shaft 26) as illustrated by a solid line in FIG. 1, both the drive gears 17a and 18a are not connected to the input shaft 15. In the cases where the fork shaft 26 and the shift fork 25 are brought to move by a shift lever (not shown) in an upward direction in FIG. 1 to thereby cause the sleeve 21 to move in the same direction, the first synchronizer ring 22a is pressed by a shifting key (not shown) provided at the sleeve 21. Then, the first synchronizer ring 22a frictionally engages through the conical surface thereof with the first gear piece 23a. The external spline formed at the outer periphery of the first synchronizer ring 22a engages with the internal spline 21b of the sleeve 21 so that rotations of the first drive gear 17a are synchronized with rotations of the input shaft 15. Next, the external spline formed at the outer periphery of the first gear piece 23a engages with the internal spline 21b of the sleeve 21 so that the first drive gear 17a is connected to the input shaft 15. As a result, the power transmission is performed between the input shaft 15 and the output shaft 16 by means of the first gear train 17a and 17b.

In the cases where the fork shaft 26 and the shift fork 25 are brought to move by the shift lever in a downward direction in FIG. 1, rotations of the second drive gear 18a are synchronized with rotations of the input shaft 15. Then, the external spline formed at the outer periphery of the second gear piece 23b engages with the internal spline 21b of the sleeve 21 so that the second drive gear 18a is connected to the input shaft 15. As a result, the power transmission is performed between the input shaft 15 and the output shaft 16 by means of the second gear train 18a and 18b. In the same way, though an illustration is omitted, the third drive gear 19a, or the like is selectively connected to the input shaft 15 in the same way so that the power transmission is performed between the input shaft 15 and the output shaft 16 by means of the third gear train 19a and 19b, or the like.

As illustrated in FIG. 2, the rotation speed sensor 30 includes a detection portion 31 provided by penetrating through the casing 10, and the magnetic portion 32 having a round bar shape and projecting from an inner end of the detection portion 31. A surface of the magnetic portion 32 is positioned in a direction perpendicular to a magnetization direction thereof and arranged adjacent to and facing teeth portions 17b1 (projection, member) formed at the outer periphery of the iron-made driven gear 17b serving as a magnetic material. The detection portion 31 includes a magnetic coil by means of which dynamic variations in a magnetic field generated by the magnetic portion 32 upon a circumferential movement of the teeth portions 17b1 is detected to thereby detect a rotation speed of each of the driven gear 17b and the output shaft 16.

The stroke position sensor 35 includes a detection portion 36 provided by penetrating through the casing 10, and the magnetic portion 37 having a plate shape and magnetized in a thick direction thereof. Precisely, the magnetic portion 37 is provided at a projecting portion 25b of the shift fork 25 projecting towards the detection portion 36 so as to face the detection portion 36. A pail of detection elements such as a lead switch, hall element, and magnetic resistive element is arranged at a tip end portion of the detection portion 36 while keeping a predetermined distance between the elements in a movement direction of the shift fork 25. The detection portion 36 then detects the variations in a magnetic field generated by the magnetic portion 37 that moves along with the shift fork 25 to thereby detect the stroke position of the shift fork 25. According to the present embodiment, alternatively, a pair of magnetic portions 37 may be provided at the shift fork 25 while keeping a predetermined distance between the magnetic portions 37 in the moving direction of the shift fork 25. Then, one detection element may be provided at the tip end portion of the detection portion 36.

As illustrated in FIGS. 1 to 3, the lubricant supply pump 40 suctions the lubricant stored at the bottom portion of the casing 10 through an oil filter 41 and a suction pipe 40a, and then discharges the lubricant to the first lubricant supply pipe 42, the second lubricant supply pipe 43, and a third lubricant supply pipe 44. An ejection nozzle 42a is provided at an end portion of the first lubricant supply pipe 42 so as to extend towards the magnetic portion 32 of the rotation speed sensor 30. The lubricant suctioned from the lubricant supply pump 40 through the first lubricant supply pipe 42 and sent to a tip end of the ejection nozzle 42a is ejected towards the tip end portion of the magnetic portion 32 that is exposed into the casing 10, precisely, towards a portion between the tip end portion of the magnetic portion 32 and each of the teeth portions 17b1 of the driven gear 17b as illustrated by an arrow F1 in FIG. 2. In addition two ejection nozzles 43a are provided at an end portion of the second lubricant supply pipe 43 so as to extend towards a tip end portion of the stroke position sensor 35. Respective end portions of the ejection nozzles 43a are crushed so as to form into an elongated shape in a cross section, i.e., elongated in a direction parallel to the fork shaft 26 as illustrated in FIG. 1. The ejection nozzles 43a are aligned in a longitudinal direction of the second lubricant supply pipe 43. The lubricant suctioned from the lubricant supply pump 40 through the second lubricant supply pipe 43 and sent to each tip end of the ejection nozzles 43a is ejected towards a surface of the detection portion 36 that is exposed into the casing 10, precisely, towards a portion between the detection portion 36 and the magnetic portion 37 as illustrated by an arrow F2 in FIG. 2 while the ejection of the lubricant forms into a flat shape substantially in parallel with the fork shaft 26. The lubricant sent from the lubricant supply pump 40 to the third lubricant supply pipe 44 is supplied to portions where the lubricant is required (i.e., lubricated portions), such as a bearing portion and a mesh portion of gears, in the transmission.

According to the aforementioned embodiment, in the cases where the output shaft 16 and the driven gear 17b are brought to rotate, the respective teeth portions 17b1 of the driven gear 17b made of magnetic material move in the circumferential direction and pass in the vicinity of the magnetic portion 32 one after another. As a result, the magnetic field generated by the magnetic portion 32 dynamically varies. The detection portion 31 including the magnetic coil, and the like detects the dynamic variations of the magnetic field to thereby detect each of the rotation speeds of the driven gear 17b and the output shaft 16. In the casing 10 of the transmission, fine iron powder generated at a bearing portion, a mesh portion of gears, and the like is mixed into the lubricant. Such iron powder mixed into the lubricant is absorbed by the magnetic portion 32 of the detection portion 31 and is stored thereat, which leads to a change of the magnetic path. Accordingly, the variation state of the magnetic field is changed to thereby induce a detection error in each of the rotation speeds of the driven gear 17b and the output shaft 16. However, according to the present embodiment, because of the lubricant ejected from the tip end of the ejection nozzle 42a of the first lubricant supply pipe 42 to the portion between the tip end portion of the magnetic portion 32 and each of the teeth portions 17b1 of the driven gear 17b, the iron powder is prevented from being absorbed by the surface of the magnetic portion 32. In addition, the iron powder once absorbed by the surface of the magnetic portion 32 is removed therefrom. Therefore, the change of the magnetic path in the vicinity of the magnetic portion 32 and the change of variation state of the magnetic field because of the absorption of the iron powder are prevented to thereby maintain reliability of a gear shift control system of the transmission.

In addition, according to the aforementioned embodiment, the lubricant provided from the tip end of the ejection nozzle 42a is ejected to the portion between the tip end portion of the magnetic portion 32, where the highest magnetic field density is generated and thus the iron powder is intensively absorbed, and each of the teeth portions 17b1 of the first driven gear 17b. Thus, the iron powder absorbed by the magnetic portion 32 is most effectively removed. However, the present invention is not limited to the above and at least the lubricant may be ejected towards the magnetic portion 32 that is exposed within the casing 10. In such a manner, effects that the iron powder absorbed by the magnetic portion 32 is removed and that the detection error in the rotation speed is prevented can be still obtained.

Further, in the neutral position of the transmission indicated by the solid line in FIG. 1, the magnetic portion 37 of the stroke position sensor 35 is positioned between the two detection elements, which are therefore not activated by the magnetic portion 37. Then, in the cases where the shift fork 25 moves upward to a position shown by a chain double-dashed line 25A in FIG. 1 and thus the sleeve 21 is in a position shown by a chain double-dashed line 21A, the magnetic portion 37 reaches a position shown by a chain double-dashed line 37A at which the magnetic portion 37 faces one of the detection elements to thereby activate that detection element. As a result, the stroke position sensor 35 detects that the first drive gear 17a is connected to the input shaft 15. In the same way, in the cases where the shift fork 25 moves downward to a position shown by a chain double-dashed line 25B in FIG. 1 and thus the sleeve 21 is in a position shown by a chain double-dashed line 21B3, the magnetic portion 37 reaches a position shown by a chain double-dashed line 37B at which the magnetic portion 37 faces the other one of the detection elements to thereby activate that detection element. As a result, the stroke position sensor 35 detects that the second drive gear 18a is connected to the input shaft 15. In the aforementioned states, the iron powder mixed into the lubricant in the casing 10 may be possibly absorbed by the magnetic portion 37 provided at the shift fork 25 and be stored thereat to thereby change the magnetic path and the magnetic field state. Then, the possible detection error in the stroke position of the shift fork 25 may cause the detection error of whether or not each of the drive gears 17a and 18a, for example, is connected to the input shaft 15. However, in such case, the lubricant is ejected from the tip end of each of the ejection nozzles 43a of the second lubricant supply pipe 43 towards the portion between the magnetic portion 37 and the tip end portion of the detection portion 36. Additionally, the lubricant forms into a flat shape substantially in parallel with the fork shaft 26 so that the iron powder is prevented from being absorbed by the surface of the magnetic portion 37 regardless of the position of the magnetic portion 37 that moves along with the shift fork 25. The iron powder, once absorbed by the surface of the magnetic portion 32, can be also removed therefrom. As a result, the change of the magnetic path in the vicinity of the magnetic portion 37 and then the change of the magnetic field state, because of the absorption of iron powder, are prevented to thereby avoid the detection error in the stroke position of the shift fork 25. The reliability of the gear shift control system of the transmission is ensured, accordingly.

In the aforementioned case, the lubricant provided from the tip end of each of the ejection nozzles 43a is ejected to the portion between the tip end portion of the magnetic portion 37, where the highest magnetic field density is generated and thus the iron powder is intensively absorbed, and the tip end portion of the detection portion 36. Thus, the iron powder absorbed by the magnetic portion 37 is most effectively removed. However, the present invention is not limited to the above and at least the lubricant may be ejected towards the magnetic portion 37 that is exposed Within the casing 10. In such a manner, effects that the iron powder absorbed by the magnetic portion 37 is removed and that the detection error in the stroke position of the shift fork 25 is prevented can be still obtained.

Further, according to the aforementioned embodiment, the lubricant is provided to portions where the lubricant is required in the transmission. Thus, the lubricant supply pump that supplies the lubricant for removing iron powder absorbed by each surface of the magnetic portions 32 and 37 can be also used as the pump for lubrication. As a result, the structure of the transmission can be simplified to thereby reduce the manufacturing cost thereof. However, the present embodiment is not limited to the above and is achieved by a usage of an exclusive lubricant supply pump. With the usage of such pump, the detection error in the operation state of the transmission can be prevented and the effect of maintaining the reliability of the gear shift control system can be obtained.

Furthermore, according to the aforementioned embodiment, the lubricant sent from the lubricant supply pump 40 is ejected through each of the lubricant supply pipes 42 and 43 towards each of the magnetic portions 32 and 37 both of which are exposed within the casing 10. Thus, the iron powder is prevented from being absorbed by the surfaces of the magnetic portions 32 and 27 of the sensors 30 and 35, respectively. In addition, the iron powder once absorbed by the surfaces of the magnetic portions 32 and 37 can be removed therefrom. Therefore, the iron powder is prevented from being intensively absorbed by the magnetic portions 32 and 37 of the sensors 30 and 35. The change of the magnetic field generated by the magnetic portions 32 and 37 because of the absorption of the iron powder to thereby adversely affect the operation of each of the sensors 30 and 35, or the detection error in the operating state of the transmission can be avoided. The reliability of the gear shift control system of the transmission can be maintained accordingly.

Furthermore, according to the aforementioned embodiment, the lubricant supply pump 40 supplies the lubricant to a portion where the lubricant is required in the transmission.

Furthermore, according to the aforementioned embodiment, the magnetic portion 32 of the rotation speed sensor 30 is provided at a portion of the detection portion 31 attached to the casing 10, the magnetic portion 32 generating the magnetic field that is changed in response to a movement of the teeth portions 17b1 made of a magnetic material, and the first lubricant supply pipe 42 ejects the lubricant to a portion between the magnetic portion 32 and the teeth portions 17b1.

The lubricant is ejected towards the portion between each of the teeth portions 17b1 and the magnetic portion 32 that may most adversely affect the operation of the rotation speed sensor 30 in the cases where the iron powder is absorbed by the magnetic portion 32. Thus, the iron powder can be most effectively removed.

Furthermore, the magnetic portion 36 of the stroke position sensor 35 is provided at the shift fork 25 that is moved in a case where one of the gear trains is selected, the magnetic portion 36 generating the magnetic field that is changed in response to a movement of the shift fork 25, and the second lubricant supply pipe 43 ejects the lubricant to a portion between the magnetic portion 37 and the detection portion 36.

The lubricant is ejected towards the detection portion 36 and the magnetic portion 37, which may most adversely affect the operation of the stroke position sensor 35 when the iron powder is absorbed by the magnetic portion 37. Thus, the iron powder can be most effectively removed.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

1. A transmission comprising:
first and second transmission shafts (15, 16) arranged parallel to each other and rotatably supported in a casing (10);
plural gear trains (17a, 17b, 18a, 18b, 19a, 19b) arranged between the first and second transmission shafts, each gear train including a drive gear (17a, 18a, 19a) and a driven gear (17b, 18b, 19b) engaging with each other, the first and second transmission shafts transmitting power therebetween by means of one of the gear trains;
a magnetic sensor device (30, 35) including a magnetic portion (32, 37) generating a magnetic field and a detection portion (31, 36) detecting a change of the magnetic field generated by the magnetic portion;
a lubricant supply pump (40) for suctioning a lubricant stored at a bottom portion in the casing and for sending the lubricant suctioned; and
a lubricant supply pipe (42, 43) for ejecting the lubricant sent from the lubricant supply pump to the magnetic portion (32, 37) exposed within the casing.

2. A transmission according to claim 1, wherein the lubricant supply pump (40) supplies the lubricant to a portion where the lubricant is required in the transmission.

3. A transmission according to claim 1, wherein the magnetic portion (32) of the magnetic sensor device (30) is provided at a portion of the detection portion (31) attached to the casing (10), the magnetic portion (32) generating the magnetic field that is changed in response to a movement of a projection member (17b1) made of a magnetic material, and the lubricant supply pipe (42) ejects the lubricant to a portion between the magnetic portion (32) and the projection member (17b1).

4. A transmission according to claim 2, wherein the magnetic portion (32) of the magnetic sensor device (30) is provided at a portion of the detection portion (31) attached to the casing (10), the magnetic portion (32) generating the magnetic filed that is changed in response to a movement of a projection member (17b1) made of a magnetic material, and the lubricant supply pipe (42) ejects the lubricant to a portion between the magnetic portion (32) and the projection member (17b1).

5. A transmission according to claim 3, wherein the projection member is equal to a teeth portion (17b1) of the driven gear of the gear train.

6. A transmission according to claim 4, wherein the projection member is equal to a teeth portion (17b1) of the driven gear of the gear train.

7. A transmission according to claim 1, wherein the magnetic portion (36) of the magnetic sensor device (35) is provided at an operation member (25) that is moved in a case where one of the gear trains is selected, the magnetic portion generating the magnetic field that is changed in response to a movement of the operation member, and the lubricant supply pipe (43) ejects the lubricant to a portion between the magnetic portion (37) and the detection portion (36).

8. A transmission according to claim 2, wherein the magnetic portion (36) of the magnetic sensor device (35) is provided at an operation member (25) that is moved in a case where one of the gear trains is selected, the magnetic portion generating the magnetic field that is changed in response to a movement of the operation member, and the lubricant supply pipe (43) ejects the lubricant to a portion between the magnetic portion (37) and the detection portion (36).

9. A transmission according to claim 7, wherein the operation member is equal to a shift fork (25) for selecting one of the gear trains.

10. A transmission according to claim 8, wherein the operation member is equal to a shift fork (25) for selecting one of the gear trains.
